(19) United States
(12) Patent Application Publication
(10) Pub. No.: US 2007/0040630 A1
(43) Pub. Date: Feb. 22, 2007

(54) Electronic circuit unit having low transmission loss

(75) Inventor: Kazuharu Aoki, Fukushima-ken (JP)

Correspondence Address: BEYER WEAVER & THOMAS, LLP, P.O. BOX 70250, OAKLAND, CA, 94612-0250, US

(73) Assignee: ALPS ELECTRIC CO., LTD.

(21) Appl. No.: 11/451,942

(22) Filed: Jun. 12, 2006

(30) Foreign Application Priority Data
Aug. 22, 2005 (JP) 2005-240246

(51) Int. Cl. H03H 7/38

(52) U.S. Cl. 333/33

(57) ABSTRACT

In an electronic circuit unit for transmitting power through a transmission line 103 formed of a conductor pattern, a matching circuit 101 is connected to an output end of a power amplifier 102. The matching circuit 101 comprises a first conductor pattern 14 having bend portions P1 to P4 provided on a first dielectric substrate 11 of a laminated substrate 10 which has a plurality of dielectric layers 11 to 13, and a second conductor pattern 15 disposed opposite the first conductor pattern 14 on an adjacent second dielectric layer 12, and connecting conductors 16 to 20 provided at at least bend portions P1 to P4 of the first and second conductor patterns.

### FIELD OF THE INVENTION

The present invention relates to an electronic circuit unit having a transmission line for transmitting a high-frequency signal.

### DESCRIPTION OF THE RELATED ART

Conventionally, in a high frequency circuit, an impedance matching is performed between circuits by a matching circuit so as to transmit power without loss.

FIG. 6 is shows a matching circuit disposed at an output stage of a power amplifier. Since the matching circuit 101 is disposed at an output end of the power amplifier 102, an output of the power amplifier 102 is transmitted to a load of a rear stage through a transmission line 103 of the matching circuit 101. A parallel resonance circuit consisting of a power feeding line 105 grounded through a by-pass capacitor 104 and an output capacitor 106 is connected to a collector of a transistor 107. Meanwhile, one capacitor 118 is serially connected to an output side of the transmission line 103, and the other capacitor 119 is parallelly connected.

In the matching circuit 101, current is supplied between a collector and an emitter of the transistor 107 through the power feeding line 105. In this case, impedance becomes infinite by parallelly resonating the parallel resonance circuit consisting of the power feeding line 105 and the output capacitor 106. Accordingly, a power loss in the parallel resonance circuit can be made to zero ideally. Further, a reflection of power is suppressed by matching the impedance of the power amplifier 102 with the impedance of the load connected to the rear using stage the transmission line 103 and two capacitors 118 and 119, thereby preventing a power loss caused by an impedance mismatching.

FIG. 7 is an explanary view showing a cross sectional structure when a transmission line 103 is constituted by a microstrip line. A conductor 111 of an upper surface is a transmission line 103, and a conductor 112 of a lower surface is a ground. A dielectric substrate 113 is constituted by a plurality of dielectric layers 113a to 113c, and a power amplifier 102 and a transistor 107 are formed on the dielectric substrate 113.

However, even though the impedance matching is performed in the matching circuit 101, since current having a level corresponding to a resistance value of a conductor 111 constituting the transmission line 103 flows to the transmission line 103, a the conductor loss can not be completely prevented. Meanwhile, in the upper surface of the dielectric substrate 113 required to be miniaturized, it is limited that the thickness and width of the conductor 111 is secured, whereby the resistance value is decreased.

Moreover, it is known that the conductor thickness is equivalently improved by providing a conductor pattern of same shape on each upper surface of a laminated substrate formed of a plurality of dielectric layers and parallelly connecting both ends of the conductor pattern formed on an adjacent layer with a through hole (for example, refer to Patent Document 1).

In order to efficiently secure a length of a transmission line in a limited space, it is preferable to make a conductor in a complicated shape (for example, a spiral pattern) having a plurality of bend sections. But, there is a problem that an electric field is concentrated on the bend section of the conductor pattern when high frequency current flows to the transmission line having such bend sections, thereby causing the transmission loss.

### SUMMARY OF THE INVENTION

An object of the present invention is to provide an electronic circuit capable of decreasing a resistance value by equivalently increasing a thickness of a conductor pattern constituting a transmission line and suppressing a transmission loss due to a concentration of an electric field at a bend section even in the conductor pattern having a bend section.

An electronic circuit unit having a low transmission loss, comprises a laminated substrate having a plurality of dielectric layers, a first conductor pattern that is provided on a surface layer or an inner layer of the laminated substrate and has a bend section, a second conductor pattern that is provided on an adjacent layer to the first conductor pattern to dispose opposite the first conductor pattern, and a connecting conductor that is provided at at least a bend section of the first and second conductor patterns and that conductively connects the first and second conductor patterns, wherein, power is transmitted through a transmission line formed of the first and second conductor patterns.

By this configuration, power is transmitted through the transmission line constituted by the first and second conductor patterns. However, since the connecting conductor conductively connecting the first and second conductor patterns is provided on the bend section of the first and second conductor patterns, the surface area of the bend section on which an electric field is concentrated is reduced, thereby reducing a transmission loss.

In the invention, the electronic circuit unit comprises a power amplifier provided on the laminated substrate, and an impedance matching circuit connected to an output end of the power amplifier, including the first and second conductor patterns and the connecting conductor.

By this configuration, power can be transmitted with a high-efficiency by matching the impedance between the power amplifier and a load of a rear stage by the impedance matching circuit in addition to reduce the resistance value of the transmission line in the impedance matching circuit, thereby decreasing the loss.

In the electronic circuit unit of the invention, the connecting conductor is provided at a straight section of the first and second conductor patterns, and conductively connects the first and second conductor patterns in the straight section.

Accordingly, since it is conductively connected by the connecting conductor in the straight line portion of the first and second conductor patterns, the surface area of the conductor pattern, thereby decreasing the transmission loss.

In the electronic circuit unit of the invention, the dielectric layer interposed between the first and the second patterns has a thickness thinner than that of the dielectric layer adjacent thereto.

A height of the connecting conductor is reduced when the connecting conductor is formed by metal plating, so that the forming time can be reduced. The height of the connecting conductor corresponds to the thickness of the dielectric layer, but the height of the connecting conductor may increase when the thickness of the dielectric layer corresponds to that of the other dielectric layer. Accordingly, the height of the connecting conductor is reduced by forming the dielectric layer including the connecting conductor thinner than that of the adjacent dielectric layer so that the time of forming the plated metal layer is shortened.

In the electronic circuit unit of the invention, the connecting conductor is a cylindrical body or a long body that a conductive material is filled in a through hole connecting the first conductor pattern and the second conductor pattern in a solid form.

Therefore, since the connecting conductor for connecting the first and second conductor patterns is the cylindrical body or the long body filled with the conductive material in a solid form and that is not in a hollow form, the surface area of the connecting conductor increases and the resistance value of the conductor pattern decreases, thereby decreasing the transmission loss.

The electronic circuit of the invention comprises providing the second conductor pattern on the inner layer of the laminated substrate, forming a barrier metal having a resistance characteristics when a metal plating layer is etched on a surface of the second conductor pattern, forming the metal plating layer by the metal plating on the inner layer, forming the connecting conductor by selectively etching the metal plating layer, forming a dielectric layer by coating or laminating the thermosetting dielectric material, forming the surface layer on which the surface of the connecting conductor is exposed by grinding the surface of the dielectric layer, and providing the first conductor pattern on the surface layer on which the surface of the connecting conductor is exposed.

Therefore, there is provided the connecting conductor formed of the cylindrical body or the long body filled with the conductive material in a solid form and that is not in a hollow form

According to the invention, it is possible to provide an electronic circuit capable of decreasing a resistance value by equivalently thickening a thickness of a conductor pattern constituting a transmission line in addition to suppressing a transmission loss due to a concentration of an electric field in a bend section even in the conductor pattern having a bend section.

### BRIEF DESCRIPTION OF THE DRAWINGS

FIG. 1A is a plane view of a transmission line in an electronic circuit unit according to an embodiment, and FIG. 1B is a cross-sectional view taken along a line A-A in FIG. 1A.

FIG. 2A is a top view showing a region R in FIG. 1, and FIG. 2B is a cross-sectional view taken along a line B-B in FIG. 2A.

FIG. 3 shows a manufacturing process of a first and a second conductor patterns and a connecting conductor in the embodiment.

FIG. 4A is a plane view of a transmission line in an electronic circuit unit which transforms a connecting conductor, and FIG. 4B is a cross-sectional view taken along a line C-C in FIG. 4A.

FIG. 5A is a plane view of a transmission line in an electronic circuit unit which transforms a connecting conductor, and FIG. 5B is a cross-sectional view taken along a line D-D in FIG. 5A.

FIG. 6 is an explanary view showing a configuration of a conventional electronic circuit unit.

FIG. 7 is a partial cross-sectional view of a transmission line in FIG. 6.

### DESCRIPTION OF THE PREFERRED EMBODIMENT

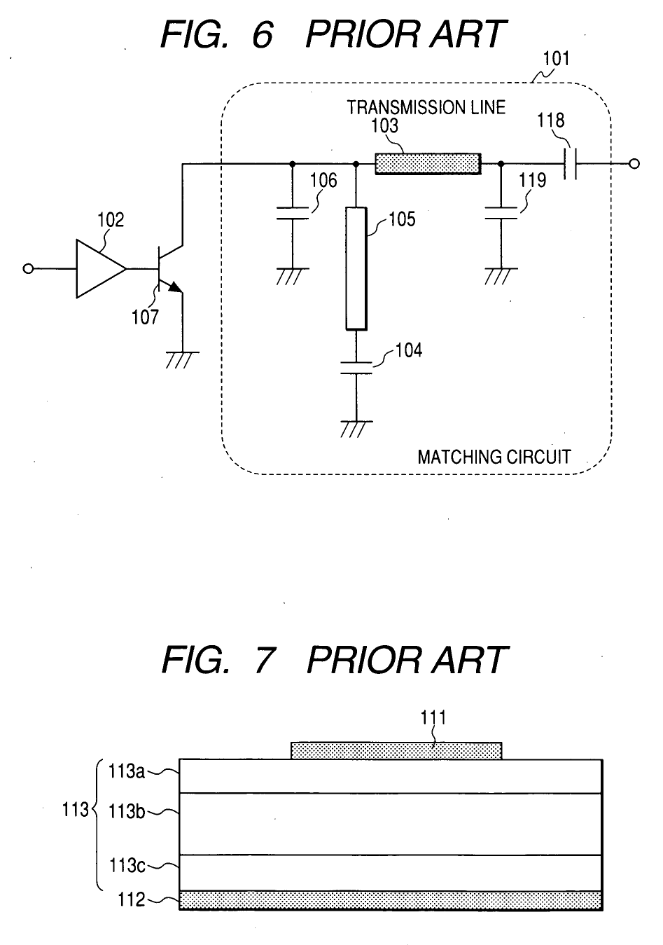

Hereinafter, the embodiments of the present invention will be specifically described with reference to the accompanying drawings. A configuration of an electronic circuit unit according to the present embodiment is same as the circuit configuration shown in FIG. 6. That is, the electronic circuit unit has the configuration in which a matching circuit 101 is connected to an output end of a power amplifier 102 and an impedance matching is obtained between the power amplifier 102 and a load of a rear stage by a matching circuit.

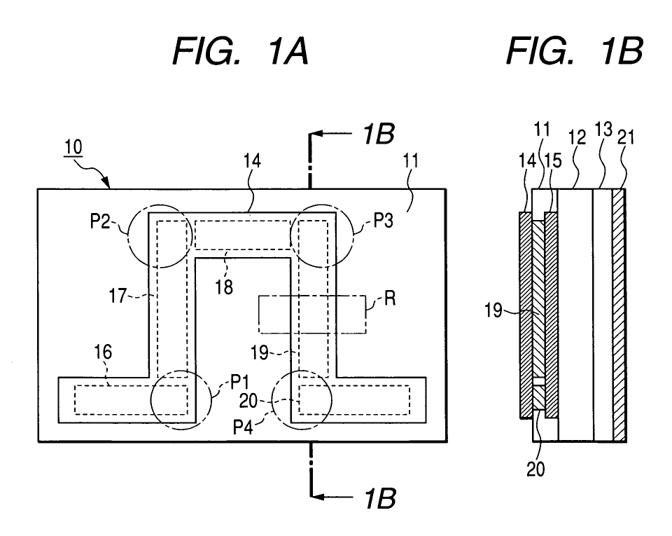

FIG. 1A and FIG. 1B are a plan view and a cross-sectional view of a transmission line in the electronic circuit unit according to an embodiment. As shown in FIGS. 1A and 1B, a laminated substrate 10 is constituted by a plurality of dielectric layers of a first dielectric layer 11, a second dielectric layer 12 and a third dielectric layer 13. A first conductor pattern 14 having a plurality of bend sections is formed on a surface of the first dielectric layer 11 which is a surface layer of the laminated substrate 10. Further, as shown in FIG. 1B, a second conductor pattern 15 is formed on a surface of the second dielectric layer 12 which is an adjacent layer of the first dielectric layer 11 in which the first conductor pattern 14 is formed. The first conductor pattern 14 and the second conductor pattern 15 have the same shape. In the embodiment, the first and second conductor patterns 14 and 15 are formed by a rectangular-wave shape to have four bend sections P1 to P4 as shown in FIG. 1A. The first and second conductor patterns 14 and 15 having the same shape are disposed opposite each other through the first dielectric layer therebetween.

As described above, the first and second conductor patterns 14 and 15 which have the same shape and are disposed opposite each other are conductively connected through the connecting conductors 16 to 20 of a plurality of conductive long body. As shown in FIG. 1A, the first and second conductor patterns 14 and 15 are conducted through the connecting conductor 16 (right end portion) in the bend section P1. In this manner, the first and second conductor patterns 14 and 15 are connected through the connecting conductor 17 (upper end portion) in the bend section P2, through the connecting conductor 19 (upper end portion) in the bend section P3 and through the connecting conductor 220 (left end portion) in the bend section P4. That is, the first conductor pattern 14 and the second conductor pattern 15 are conducted through the connecting conductors in the at least bend sections P1 to P4 of the first and second conductor patterns 14 and 15.

In the embodiment, five connecting conductors 16 to 20 are provided corresponding to five straight sections of the first and second conductor patterns 14 and 15. The lengths of each of the connecting conductors 16 to 20 are set to be slightly shorter than that of each corresponding straight sections (conductor patterns 14 and 15). Further, the widths of each of the connecting conductors 16 to 20 are set to be slightly shorter than that of each corresponding straight sections (conductor pattern 14 and 15). Accordingly, the first and second conductor patterns 14 and 15 are conductively connected to a plurality of connecting conductors 16 and 20 formed of the long body corresponding to the approximate entire length of the transmission line.

Since, each of the bend sections P1 to P2 of the first and second conductor patterns 14 and 15 is formed at a intersection of two adjacent straight sections, they extend to the bend sections P1 to P4 corresponding to one end of the connecting conductors 16, 17, 19 and 20 which are disposed opposite any one of straight sections, thereby conducting the first and second conductor patterns 14 and 15.

As shown in FIG. 1B, a conductor layer 21 functioning as a ground layer is formed on a lower surface of a third dielectric layer. Moreover, although not shown in FIG. 1, a variety of patterns or wirings constituting a element such as a power amplifier 102, a transistor 107 and power feeding line 105 are provided on any one of surfaces of the first, second and third dielectric layers 11, 12 and 13 in the laminated substrate 10, and the patterns are connected each other through a through hole formed on each dielectric layers 11 to 13 if necessary.

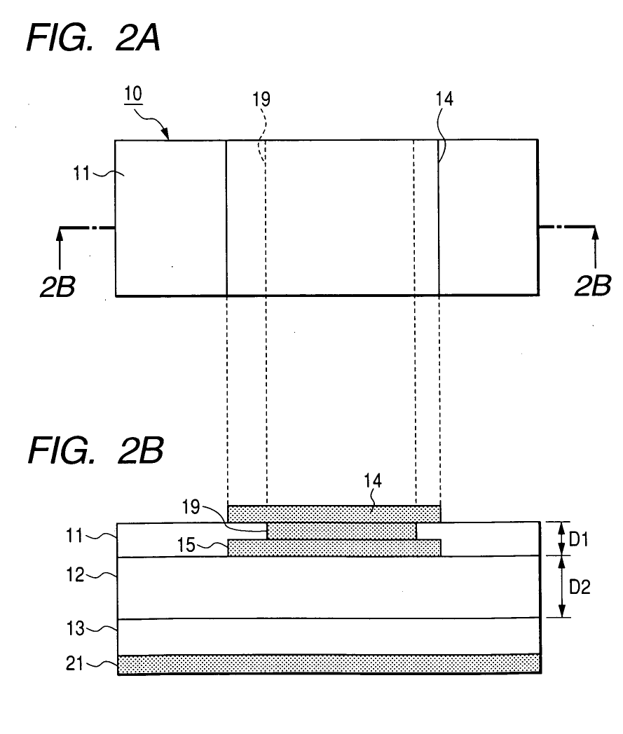

FIG. 2A is a plan view of a region R shown in FIG. 1A, and FIG. 2B is a cross-sectional view taken along a line B-B shown in FIG. 2A. As shown in FIG. 2B, a thickness D1 of the first dielectric layer formed between the first conductor pattern 14 and the second conductor pattern 15 is set to be thinner than a thickness D2 of the adjacent second dielectric layer 12. In case of forming the connecting conductors 16 to 20 by plating, the time of forming a metal layer by plating takes long when the thickness of the connecting conductors 16 to 20 is thick. Therefore, the thickness of the first dielectric layer 11 is set to be thin in a level capable of insulating the first conductor pattern 14 and the second conductor pattern 15.

Here, the manufacturing process of the electronic circuit unit will be described.

For the first, the second and the third dielectric layers 11, 12 and 13, a dielectric resin such as a glass epoxy resin, an epoxy resin polyimide can be used as a material. Further, the conductor layer 21 including the conductor patterns 14 and 15, and the ground can be used by thermocompressing a copper foil. For the connecting conductors 16 to 20, a copper plating pole can be used.

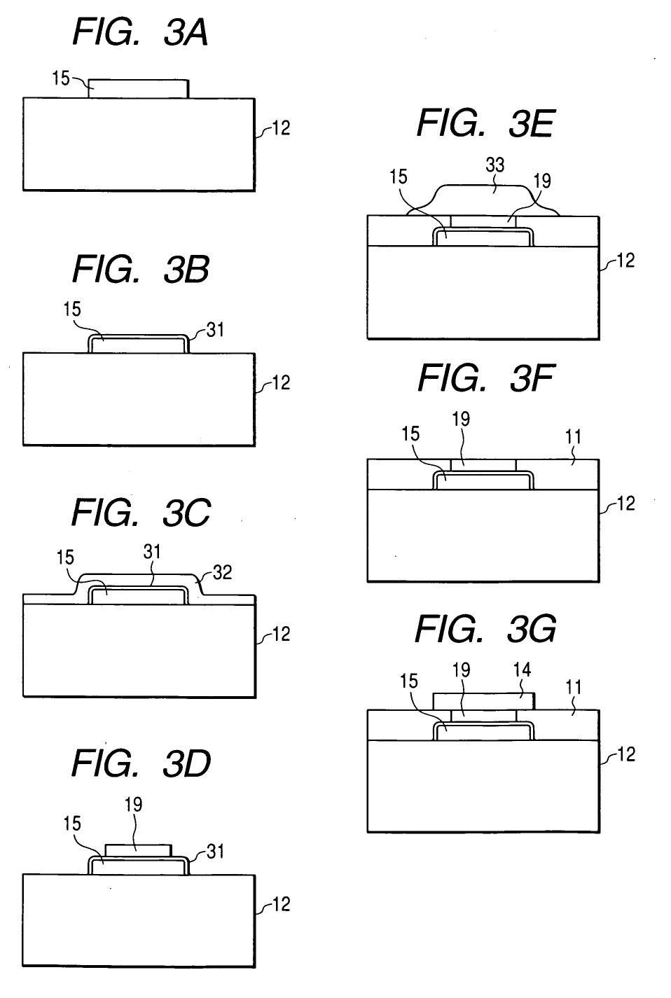

FIGS. 3A to 3G show a manufacturing process of a first and a second conductor pattern 14 and 15, and a connecting conductor.

The second conductor pattern 15 shown in FIG. 1B is formed by thermocompressing the copper foil which is cut in the rectangular-wave shape as shown in FIG. 3A. Next, a barrier metal 31 which shows a resistance characteristic in case of etching the metal plating layer is disposed on the exposing surface of the second conductor pattern 15 to cover the second conductor pattern as shown in FIG. 3B. Gold, Silver, zinc, palladium, and nikel can be used as a metal showing a resistance characteristic in case of etching the copper.

The copper plating layer 32 is formed on the entire surface of the second dielectric layer which includes the second conductor pattern 15 covered by the barrier metal 31 by electrolytic plating as shown in FIG. 3C. The electrolytic plating is performed by immersing the entire substrate into the plating solution to make the substrate as a cathode, and depositing the copper on the cathode by the electrolysis reaction to make the copper ion supplying source of the plating metal as an anode. Further, electroless plating can be used besides the electrolysis plating as shown in FIG. 3D.

Next, the copper plating layer 32 is selectively etched to remain the connecting conductor 19, whereby the connecting conductor 19 (16 to 18, 20) made of the copper plating pole is formed as shown in FIG. 3D.

Next, a dielectric material 33 for forming the first dielectric layer is applied or laminated on the top of the connecting conductor 19 (16 to 18, 20) in the surface of the second dielectric layer 12 as shown in FIG. 3E. Liquid form or sheet form of a thermosetting epoxy resin or polyimide resin can be used as the dielectric material. The thermosetting epoxy resin is applied or laminated to be thicker than that of the second conductor pattern 15 (including the barrier metal and the connecting conductors made of the copper plating pole, and then hit and hardened.

Next, the upper surface of the connecting conductor 19 (16 to 18, 20) is exposed by grinding and polishing the hardened dielectric material 33. Lastly, the first conductor pattern 14 is formed by disposing the copper foil cut in the rectangular-wave shape on the surface of the first dielectric layer 11 to dispose opposite the second conductor pattern 15 provided on the inner layer, and thermocompressing the copper foil as shown in FIG. 3G.

By this configuration of the electronic circuit unit, since the transmission line 103 transmitting the output power of the power amplifier 102 to the load of the rear stage is formed of the first and second conductor patterns 14 and 15 disposing opposite each other through the first dielectric layer 11 therebetween, the first and second conductor patterns 14 and 15 are conductively connected through the connecting conductors 16 to 20 at at least the bend sections P1 to P4, and the concentration of the electric field in the bend sections P1 to P4 is suppressed even when the high frequency current of large amount of power flows, thereby reducing the power loss.

Further, in the embodiment, since the connecting conductors 16 to 20 are provided also on the region disposing opposite the straight section of the first and second conductor patterns 14 and 15, the average surface area of the conductor pattern may increase compared to the configuration of conductively connecting only the both end portion of the first and second conductor patterns 14 and 15 and the bend sections P1 to P4, thereby further reducing the transmission loss.

Furthermore, in the electronic circuit of the invention, the shape and disposing position of the connecting conductor for conductively connecting the first and second conductor patterns 14 and 15 are not limited thereto.

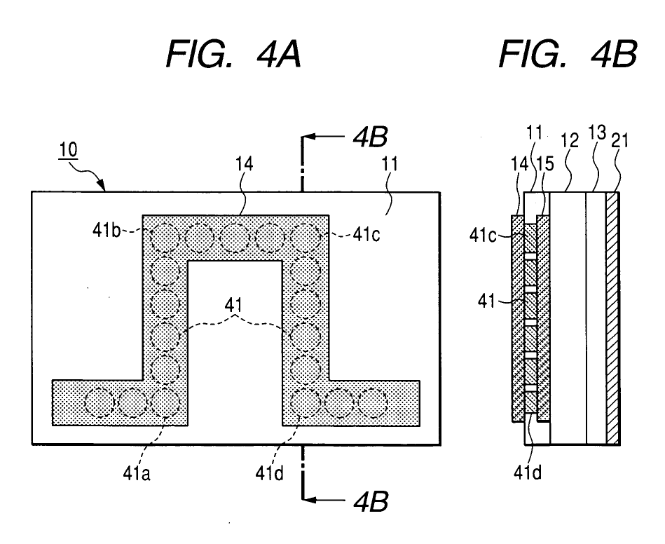

A modified example of a cylindrical connecting conductor is shown in FIGS. 4A and 4B, and has same reference numerals in the same part with each section in FIGS. 1A and 1B. The cylindrical connecting conductor 41 is formed at the straight section and the bend section of the first and second conductor patterns 14 and 15 at predetermined intervals. Particularly, each bend section of the first and second conductor patterns 14 and 15 are conductively connected on the cylindrical connecting conductors 41a to 41d. Further, the connecting conductor 41 is not limited thereto, and may have a triangular, rectangular shape.

In this manner, even when the cylindrical connecting conductors 41a to 41d are provided at the bend sections of the first and second conductor patterns 14 and 15, the concentration of the electric field in each of the bend sections is suppressed, thereby reducing the transmission loss.

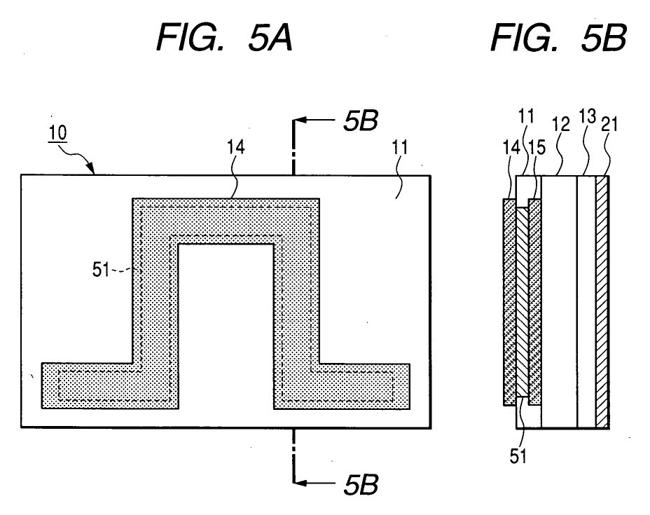

The modified example in FIGS. 5A and 5B shows a connecting conductor 51 formed as a one piece from the input end of the first and second conductor patterns 14 and 15 to the output end. As shown in FIGS. 5A and 5B, since the connecting conductor 51 conductively connects the lower surface of the first conductor pattern 14 and the upper surface of the second conductor pattern 15 across the entire length, the concentration of the electric field in each bend section can be reduced and the resistance value of the entire transmission line can be effectively reduced, thereby reducing the transmission loss.

Moreover, in the above-mentioned description, the connecting conductors 16 to 20 is made of copper pole by electrolytic plating, but they may be formed by other methods other than the electrolytic plating.

The invention can be adapted to an electric circuit unit having a transmission line for transmitting an output of a power amplifier to a load of a rear stage.

1. An electronic circuit unit having a low transmission loss, comprising:
a laminated substrate having a plurality of dielectric layers;
a first conductor pattern that is provided on a surface layer or an inner layer of the laminated substrate and has a bend section;
a second conductor pattern that is provided on an adjacent layer to the first conductor pattern to dispose opposite the first conductor pattern; and
a connecting conductor that is provided at at least a bend section of the first and second conductor patterns and that conductively connects the first and second conductor patterns,
wherein, power is transmitted through a transmission line formed of the first and second conductor patterns.

2. The electronic circuit unit having a low transmission loss according to the claim 1, comprising:
a power amplifier provided on the laminated substrate: and
an impedance matching circuit connected to an output end of the power amplifier, including the first and second conductor patterns and the connecting conductor.

3. The electronic circuit unit having a low transmission loss according to the claim 1, wherein the connecting conductor is provided at a straight section of the first and second conductor patterns, and conductively connects the first and second conductor patterns in the straight section.

4. The electronic circuit unit having a low transmission loss according to the claim 1, wherein the dielectric layer interposed between the first and the second patterns has a thickness thinner than that of the dielectric layer adjacent thereto.

5. The electronic circuit unit having a low transmission loss according to the claim 1, wherein the connecting conductor is a cylindrical body or a long body that a conductive material is filled in a through hole connecting the first conductor pattern and the second conductor pattern in a solid form.

6. The electronic circuit unit having a low transmission loss according to the claim 1, comprising:
providing the second conductor pattern on the inner layer of the laminated substrate;
forming a barrier metal having a resistance characteristics when a metal plating layer is etched on a surface of the second conductor pattern;
forming the metal plating layer by the metal plating on the inner layer;
forming the connecting conductor by selectively etching the metal plating layer;
forming a dielectric layer by coating or laminating the thermosetting dielectric material;
forming the surface layer on which the surface of the connecting conductor is exposed by grinding the surface of the dielectric layer; and
providing the first conductor pattern on the surface layer on which the surface of the connecting conductor is exposed.
